(19) United States
(12) Patent Application Publication
(10) Pub. No.: US 2024/0275359 A1
(43) Pub. Date: Aug. 15, 2024

(54) ACOUSTIC WAVE DEVICE

(71) Applicant: Murata Manufacturing Co., Ltd., Nagaokakyo-shi (JP)

(72) Inventors: Hideki IWAMOTO, Nagaokakyo-shi (JP); Akira MICHIGAMI, Nagaokakyo-shi (JP); Hiromu OKUNAGA, Nagaokakyo-shi (JP)

(21) Appl. No.: 18/536,305

(22) Filed: Dec. 12, 2023

(30) Foreign Application Priority Data
Feb. 13, 2023 (JP) 2023-019942

(51) Int. Cl. H03H 9/25; H03H 3/08; H03H 9/02; H03H 9/145

(52) U.S. Cl. CPC H03H 9/25; H03H 3/08; H03H 9/02559; H03H 9/02574; H03H 9/02637; H03H 9/02866; H03H 9/02992; H03H 9/145

(57) ABSTRACT

An acoustic wave device includes a support substrate, a piezoelectric layer on the support substrate and including first and second principal surfaces, first and second IDT electrodes respectively on the first and second principal surfaces, and a dielectric film at least provided at one of a position between the first principal surface and the first IDT electrode, and a position between the second principal surface and the second IDT electrode. Each of the dielectric film and the piezoelectric layer includes one of Li, Ta, and O or Li, Nb, and O. At least one of a polarization direction, an element included in a material, and a composition of the material is different between the dielectric film and the piezoelectric layer.

### CROSS REFERENCE TO RELATED APPLICATIONS

This application claims the benefit of priority to Japanese Patent Application No. 2023-019942 filed on Feb. 13, 2023. The entire contents of this application are hereby incorporated herein by reference.

### BACKGROUND OF THE INVENTION

### 1. Field of the Invention

The present invention relates to acoustic wave devices.

### 2. Description of the Related Art

Acoustic wave devices have been widely used in filters of mobile phones and the like. International Publication No. 2022/202917 discloses an example of an acoustic wave device. In the above-described acoustic wave device, insulating layers are provided on both principal surfaces of a piezoelectric layer. Interdigital transducer (IDT) electrodes are indirectly provided on both of the principal surfaces of the piezoelectric layer with the insulating layers interposed therebetween.

In a case where an insulating layer is provided between a piezoelectric layer and an IDT electrode as in the acoustic wave device disclosed in International Publication No. 2022/202917, the fractional band width may be adjusted by adjusting the thickness of the insulating layer. International Publication No. 2022/202917 discloses silicon nitride, silicon oxide, tantalum oxide, alumina, and silicon oxynitride as examples of the material of the insulating layer. However, the dielectric constant of the above-described materials is not sufficiently high. Because of this, in the acoustic wave device disclosed in International Publication No. 2022/202917, the size of the acoustic wave device is increased when it is attempted to obtain a desired electrostatic capacitance.

### SUMMARY OF THE INVENTION

Preferred embodiments of the present invention provide acoustic wave devices in each of which a fractional band width is able to be easily adjusted without causing an increase in size.

An acoustic wave device according to a preferred embodiment of the present invention includes a support substrate, a piezoelectric layer on the support substrate and including a first principal surface and a second principal surface opposing each other, a first IDT electrode on the first principal surface of the piezoelectric layer, and a second IDT electrode on the second principal surface of the piezoelectric layer, and a dielectric film at least provided at one of a position between the first principal surface of the piezoelectric layer and the first IDT electrode and a position between the second principal surface of the piezoelectric layer and the second IDT electrode. In the acoustic wave device, each of the dielectric film and the piezoelectric layer includes one of Li, Ta, and O or Li, Nb, and O. At least one of a polarization direction, an element included in a material, and a composition of the material is different between the dielectric film and the piezoelectric layer.

According to preferred embodiments of the present invention, a fractional band width is able to be easily adjusted without causing an increase in size.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a front cross-sectional view of an acoustic wave device according to a first preferred embodiment of the present invention.

FIG. 2 is a plan view of the acoustic wave device according to the first preferred embodiment of the present invention.

FIG. 3 is a diagram illustrating a relationship between a thickness of a dielectric film and a fractional band width in the first preferred embodiment of the present invention.

FIG. 4 is a diagram illustrating a relationship between a thickness of a dielectric film and electrostatic capacitance in the first preferred embodiment of the present invention.

FIG. 5 is a cross-sectional view taken along a line II-II in FIG. 2.

FIG. 6 is a diagram illustrating a relationship between a thickness of a dielectric film and a fractional band width in a second preferred embodiment of the present invention, a modification of the second preferred embodiment, and a first comparative example.

FIG. 7 is a diagram illustrating a relationship between a thickness of a dielectric film and a fractional band width in a third preferred embodiment of the present invention, a fourth preferred embodiment of the present invention, the first comparative example, and a second comparative example.

FIG. 8 is a front cross-sectional view illustrating the vicinity of a pair of electrode fingers of each of IDT electrodes in a fifth preferred embodiment of the present invention.

FIG. 9 is a front cross-sectional view illustrating the vicinity of a pair of electrode fingers of each of IDT electrodes in a sixth preferred embodiment of the present invention.

FIG. 10 is a diagram illustrating a relationship between a thickness of a dielectric film and a fractional band width in the first preferred embodiment of the present invention, the fifth preferred embodiment of the present invention, the sixth preferred embodiment of the present invention, and the first comparative example.

FIG. 11 is a diagram illustrating a relationship between a thickness of a dielectric film and electrostatic capacitance in the first preferred embodiment of the present invention, the fifth preferred embodiment of the present invention, the sixth preferred embodiment of the present invention, and the first comparative example.

FIG. 12 is a diagram illustrating phase characteristics in the vicinity of a frequency at which a higher order mode is generated in the first preferred embodiment, the fifth preferred embodiment, and the sixth preferred embodiment of the present invention.

FIG. 13A is a schematic cross-sectional view illustrating polarization directions of a first dielectric film, a second dielectric film, and a piezoelectric layer in the sixth preferred embodiment of the present invention, FIG. 13B is a schematic cross-sectional view illustrating polarization directions of the first dielectric film, the second dielectric film, and the piezoelectric layer in a first modification of the sixth preferred embodiment of the present invention, FIG. 13C is a schematic cross-sectional view illustrating polarization directions of the first dielectric film, the second dielectric film, and the piezoelectric layer in a second modification of the sixth preferred embodiment of the present invention, and FIG. 13D is a schematic cross-sectional view illustrating polarization directions of the first dielectric film, the second dielectric film, and the piezoelectric layer in a third modification of the sixth preferred embodiment of the present invention.

FIG. 14 is a diagram illustrating a relationship between a thickness of a dielectric film and a maximum value of a phase of a higher order mode generated near 1450 MHz in the sixth preferred embodiment of the present invention, the first to third modifications of the sixth preferred embodiment, and the first comparative example.

FIG. 15 is a diagram illustrating a relationship between a thickness of a dielectric film and a maximum value of a phase of a higher order mode generated near 1100 MHz in the sixth preferred embodiment of the present invention, the first to third modifications of the sixth preferred embodiment, and the first comparative example.

FIGS. 16A and 16B are front cross-sectional views describing processes performed until a second IDT electrode is provided in a non-limiting example of a manufacturing method for an acoustic wave device according to the sixth preferred embodiment of the present invention.

FIGS. 17A and 17B are front cross-sectional views describing processes performed until a dielectric layer is provided in a non-limiting example of the manufacturing method for the acoustic wave device according to the sixth preferred embodiment of the present invention.

FIGS. 18A to 18C are front cross-sectional views describing processes performed until a thickness of a piezoelectric substrate is adjusted in a non-limiting example of the manufacturing method for the acoustic wave device according to the sixth preferred embodiment of the present invention.

FIGS. 19A and 19B are front cross-sectional views describing processes performed until a first IDT electrode is provided in a non-limiting example of the manufacturing method for the acoustic wave device according to the sixth preferred embodiment of the present invention.

FIGS. 20A and 20B are cross-sectional views taken along a direction in which electrode fingers extend for describing processes performed until a first connection electrode and a second connection electrode are provided, in a non-limiting example of the manufacturing method for the acoustic wave device according to the sixth preferred embodiment of the present invention.

### DETAILED DESCRIPTION OF THE PREFERRED EMBODIMENTS

Hereinafter, preferred embodiments of the present invention will be described with reference to the drawings to clarify the present invention.

The preferred embodiments described in the present specification are merely examples, and partial replacement or combination of configurations is possible between different preferred embodiments.

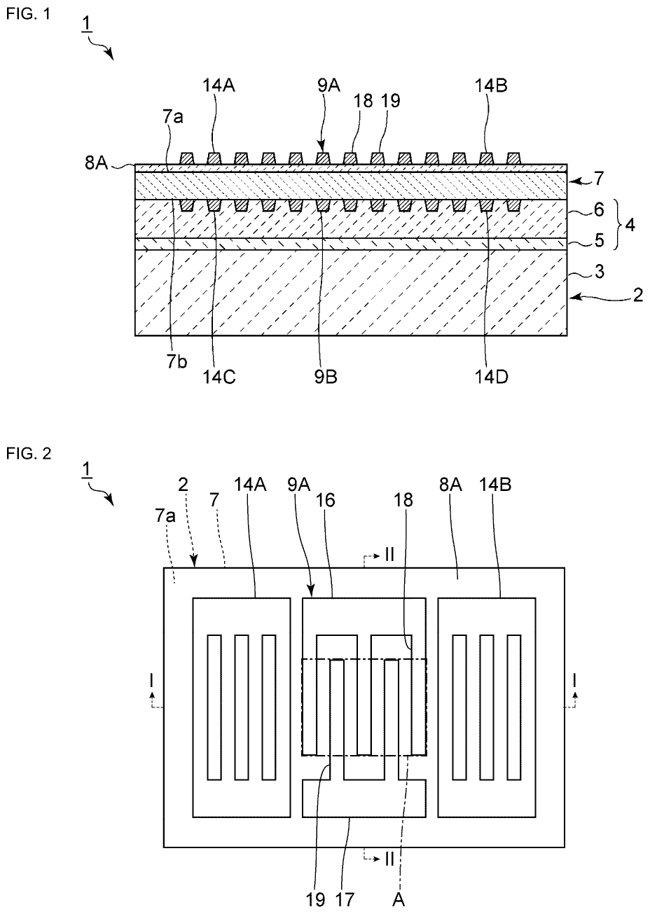

FIG. 1 is a front cross-sectional view of an acoustic wave device according to a first preferred embodiment of the present invention. FIG. 2 is a plan view of the acoustic wave device according to the first preferred embodiment. FIG. 1 is a cross-sectional view taken along a line I-I in FIG. 2. A first connection electrode, a second connection electrode, and the like, which will be described later, are omitted in FIG. 2.

As illustrated in FIG. 1, an acoustic wave device 1 includes a piezoelectric substrate 2. The piezoelectric substrate 2 includes a support substrate 3, an intermediate layer 4, and a piezoelectric layer 7. The piezoelectric substrate 2 is a substrate having piezoelectric by including the piezoelectric layer 7.

In the present preferred embodiment, the intermediate layer 4 is a multilayer body. Specifically, the intermediate layer 4 includes a first layer 5 and a second layer 6. In the piezoelectric substrate 2, the first layer 5 is provided on the support substrate 3. The second layer 6 is provided on the first layer 5. The piezoelectric layer 7 is provided on the second layer 6. The laminate structure of the piezoelectric substrate 2 is not limited to the above-described configuration. For example, the intermediate layer 4 may be a single dielectric layer. Alternatively, the intermediate layer 4 may not be provided.

Silicon, for example, is used as a material of the support substrate 3. The plane orientation of silicon used for the support substrate 3 is (100). The Euler angles (φ, θ, ψ) of the silicon are, for example, about (0°, 0°, 45°). Silicon nitride, for example, is used as a material of the first layer 5 of the intermediate layer 4. Silicon oxide, for example, is used as a material of the second layer 6. The material of the support substrate 3 and the material of each layer in the intermediate layer 4 are not limited to the above-described materials.

The piezoelectric layer 7 includes a first principal surface 7a and a second principal surface 7b. The first principal surface 7a and the second principal surface 7b oppose each other. Of the first principal surface 7a and the second principal surface 7b, the second principal surface 7b is located on the support substrate 3 side.

Lithium tantalate, for example, is used as a material of the piezoelectric layer 7. To be specific, for example, LiTaO₃ of 50° Y-cut X-propagation is used as the material of the piezoelectric layer 7. The Euler angles of LiTaO₃ used for the piezoelectric layer 7 are, for example, about (0°, 140°, 0°). The cut-angles, the Euler angles, the composition, and the material of the piezoelectric layer 7 are not limited to those described above.

It is sufficient for the piezoelectric layer 7 to include one of Li, Ta, and O or Li, Nb, and O. In other words, it is sufficient for the piezoelectric layer 7 to be an oxide layer containing Li and Ta, or Li and Nb, for example. As the material of the piezoelectric layer 7, it is preferable to use a piezoelectric single crystal which is an oxide including Li and Ta, or Li and Nb, for example. By doing so, the Q value of the acoustic wave device 1 may be suitably increased.

A dielectric film 8A is provided on the first principal surface 7a of the piezoelectric layer 7. The dielectric film 8A is a first dielectric film. Lithium niobate is used as a material of the dielectric film 8A. Specifically, LiNbO₃, for example, is used as the material of the dielectric film 8A. In the present preferred embodiment, the polarization direction of the dielectric film 8A is opposite to the polarization direction of the piezoelectric layer 7. The composition, material, and polarization direction of the dielectric film 8A are not limited to those described above. It is sufficient for the dielectric film 8A to include one of Li, Ta, and O or Li, Nb, and O. In other words, it is sufficient for the dielectric film 8A to be an oxide film including, for example, Li and Ta, or Li and Nb.

A first IDT electrode 9A is provided on the dielectric film 8A. That is, the first IDT electrode 9A is indirectly provided on the first principal surface 7a of the piezoelectric layer 7 with the dielectric film 8A interposed therebetween. A protective film may be provided on the dielectric film 8A to cover the first IDT electrode 9A. Silicon oxide, silicon nitride, silicon oxynitride, or the like, for example, may be used for the protective film.

On the other hand, a second IDT electrode 9B is provided directly on the second principal surface 7b of the piezoelectric layer 7. The second IDT electrode 9B is buried in the second layer 6 of the intermediate layer 4. The first and second IDT electrodes 9A and 9B oppose each other sandwiching the piezoelectric layer 7.

As illustrated in FIG. 2, the first IDT electrode 9A includes a first busbar 16, a second busbar 17, a plurality of first electrode fingers 18, and a plurality of second electrode fingers 19. The first busbar 16 and the second busbar 17 face each other. One end of each of the plurality of first electrode fingers 18 is connected to the first busbar 16. One end of each of the plurality of second electrode fingers 19 is connected to the second busbar 17. The plurality of first electrode fingers 18 and the plurality of second electrode fingers 19 are interdigitated with each other. The first electrode fingers 18 and the second electrode fingers 19 are connected to potentials different from each other. Hereinafter, the first electrode fingers 18 and the second electrode fingers 19 are simply referred to as electrode fingers in some cases.

Similar to the first IDT electrode 9A, the second IDT electrode 9B illustrated in FIG. 1 also includes a pair of busbars and a plurality of electrode fingers. An electrode-finger pitch of the first IDT electrode 9A is equal or substantially equal to an electrode-finger pitch of the second IDT electrode 9B. The electrode-finger pitch is a center-to-center distance of adjacent electrode fingers that are connected to different potentials from each other. In the present specification, the phrase “the electrode-finger pitches are equal” includes a case where the electrode-finger pitches are different within an error range that does not affect the electrical characteristics of the acoustic wave device.

An acoustic wave is excited by applying an alternating voltage to the first IDT electrode 9A and the second IDT electrode 9B. In the present preferred embodiment, in each of the first IDT electrode 9A and the second IDT electrode 9B, the acoustic wave propagation direction is orthogonal or substantially orthogonal to a direction in which the plurality of electrode fingers extend. A pair of reflectors 14A and 14B is provided on both sides of the first IDT electrode 9A in the acoustic wave propagation direction. Similarly, a pair of reflectors 14C and 14D is provided on both sides of the second IDT electrode 9B in the acoustic wave propagation direction. The acoustic wave device 1 is, for example, a surface acoustic wave device.

The above two pairs of reflectors may have the same potential as any one of the electrode fingers of the first IDT electrode 9A or may have the same potential as any one of the electrode fingers of the second IDT electrode 9B. Alternatively, each reflector may be a floating electrode, for example. The floating electrode refers to an electrode that is connected to neither of a signal potential and a ground potential.

The first IDT electrode 9A, the second IDT electrode 9B, and the reflectors are each made of a laminate metal film. To be specific, the layer configuration of the first IDT electrode 9A is a configuration in which, for example, a Ti layer and an Al layer are laminated in this order from the piezoelectric layer 7 side. The layer configurations of the reflector 14A and the reflector 14B are the same. The layer configuration of the second IDT electrode 9B includes a Pt layer and an Al layer that are laminated in this order from the piezoelectric layer 7 side. The layer configurations of the reflector 14C and the reflector 14D are the same. However, the materials of the first IDT electrode 9A, the second IDT electrode 9B, and the reflectors are not limited to those described above. Alternatively, the first IDT electrode 9A, the second IDT electrode 9B, and each reflector may be made of a single-layer metal film.

The following configurations are featured in the present preferred embodiment. 1) Each of the dielectric film 8A and the piezoelectric layer 7 includes one of Li, Ta, and O or a configuration including Li, Nb, and O. 2) At least one of the polarization direction, an element contained in the material, and the composition of the material is different between the dielectric film 8A and the piezoelectric layer 7.

In this specification, the configuration in which the polarization direction of one material and the polarization direction of the other material are different from each other includes a configuration in which one material has a polarization direction and the other material does not have a polarization direction.

The case where the composition of one material and the composition of the other material are different from each other includes a case where elements of the one material and elements of the other material are the same, and the ratio between the elements in the one material is different from the ratio between the elements in the other material. For example, when x and y are each assumed to be any positive number, in a case where y differs from x in LiTaOₓ and LiTaO_{y}, the composition of LiTaOₓ and the composition of LiTaO_{y} are different from each other.

As described above, in the acoustic wave device 1, each of the dielectric film 8A and the piezoelectric layer 7 includes one of Li, Ta, and O or Li, Nb, and O. Then, at least elements included in the materials of the dielectric film 8A and the piezoelectric layer 7 are different from each other. As a result, the fractional band width of the acoustic wave device 1 may be easily adjusted without increasing the size of the acoustic wave device 1. This point will be described in more detail below. In the acoustic wave device 1 having the configuration of the present preferred embodiment, the relationship between the thickness of the dielectric film 8A and the fractional band width was derived by simulation. The fractional band width is represented by an expression of (|fr−fa|/fr)×100 [%], where fr is a resonant frequency and fa is an anti-resonant frequency. Furthermore, in the acoustic wave device 1 having the configuration of the present preferred embodiment, the relationship between the thickness of the dielectric film 8A and the electrostatic capacitance was derived by simulation.

Design parameters of the acoustic wave device 1, from which the above-described relationships were derived, are as follows. In this case, a wavelength defined by an electrode-finger pitch is denoted as A. Specifically, when the center-to-center distance of the first and second electrode fingers 18 and 19 adjacent to each other in FIG. 1 is denoted as an electrode-finger pitch P, the wavelength λ is defined by an equation of λ=2P. In the following design parameters, the wavelength λ as a thickness reference of each member is the wavelength λ of the first IDT electrode 9A. However, the wavelength λ as the thickness reference of each member may be the wavelength λ of the second IDT electrode 9B.
Support substrate 3: material: Si, plane orientation: (100), γ in Euler angles (φ, θ, ψ): 45°, thickness: about 25λ
First layer 5: material: SiN, thickness: about 0.075λ
Second layer 6: material: SiO₂, thickness: about 0.37λ
Piezoelectric layer 7: material: LiTaO₃, cut-angle: about 50° Y, Euler angles: about (0°, 140°, 0°), thickness: about 0.3λ
Dielectric film 8A: material: LiNbO₃, cut-angle and thickness: 40° Y and 0.01λ, 33° Y and 0.02λ, 25° Y and 0.03λ, 20° Y and 0.04λ, 15° Y and 0.05λ, or 13° Y and 0.06λ
First IDT electrode 9A: layer configuration: Ti layer/Al layer from the piezoelectric layer 7 side, thickness: about 0.006λ/0.065λ from the piezoelectric layer 7 side
Second IDT electrode 9B: layer configuration: Pt layer/Al layer from the piezoelectric layer 7 side, thickness: about 0.015λ/0.1λ from the piezoelectric layer 7 side
Wavelength λ of first IDT electrode 9A and second IDT electrode 9B: about 5 μm
Duty ratio of first IDT electrode 9A and second IDT electrode 9B: about 0.45

By varying the cut-angle of the dielectric film 8A in accordance with the thickness of the dielectric film 8A, the Rayleigh wave as an unwanted wave may be reduced or prevented. The relationship between the cut-angle of the dielectric film 8A and the thickness of the dielectric film 8A is not particularly limited.

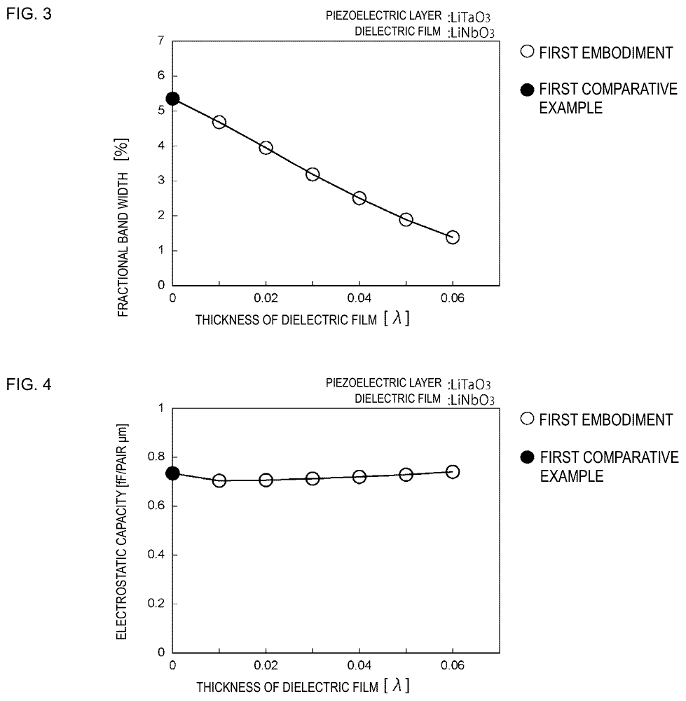

In each of FIGS. 3 and 4, a result of a first comparative example in which the thickness of the dielectric film is 0 is shown together with a result of the first preferred embodiment. The design parameters of the first comparative example are the same or substantially the same as the design parameters of the acoustic wave device 1 having the configuration of the first preferred embodiment, except that the dielectric film is not provided.

FIG. 3 is a diagram illustrating a relationship between the thickness of the dielectric film and the fractional band width in the first preferred embodiment. FIG. 4 is a diagram illustrating a relationship between the thickness of the dielectric film and the electrostatic capacitance in the first preferred embodiment. In each of FIGS. 3 and 4, a plotted portion where the thickness of the dielectric film is 0 indicates the result of the first comparative example. In FIG. 4, the electrostatic capacitance is represented as electrostatic capacitance per each portion where a pair of electrode fingers is located in each of the first IDT electrode and the second IDT electrode. The same applies to the drawings other than FIG. 4 illustrating the relationship between the thickness of the dielectric film and the electrostatic capacitance.

As illustrated in FIG. 3, it is understood that the thicker the dielectric film 8A is, the significantly smaller the value of the fractional band width is. Thus, in the first preferred embodiment, the fractional band width can be easily adjusted by changing the thickness of the dielectric film 8A.

On the other hand, as illustrated in FIG. 4, it is understood that even when the thickness of the dielectric films 8A is changed, the electrostatic capacitance of the acoustic wave device 1 hardly changes. That is, in the first preferred embodiment, even when the dielectric film 8A is provided on the piezoelectric layer 7 as illustrated in FIG. 1, the electrostatic capacitance is hardly reduced.

For example, when the dielectric film is made of silicon oxide, alumina, or the like as in the related art, the dielectric constant of the dielectric film is small. This causes the electrostatic capacitance of the multilayer body of the piezoelectric layer and the dielectric film to be small. Therefore, in the configuration in which the dielectric film is provided, it is necessary to increase the area of the multilayer body of the piezoelectric layer and the dielectric film in order to obtain a desired electrostatic capacitance.

In contrast, in the first preferred embodiment, the material of the dielectric film 8A is, for example, oxide including Li and Nb. This makes it possible to suitably increase the dielectric constant of the dielectric film 8A. In the first preferred embodiment, even when the dielectric film 8A is provided on the piezoelectric layer 7, the electrostatic capacitance of the acoustic wave device 1 is hardly reduced. The same applies to thickness adjustment of the dielectric film 8A. Accordingly, the fractional band width of the acoustic wave device 1 may be easily adjusted without increasing the size of the acoustic wave device 1.

Hereinafter, the configuration of the first preferred embodiment will be described in more detail.

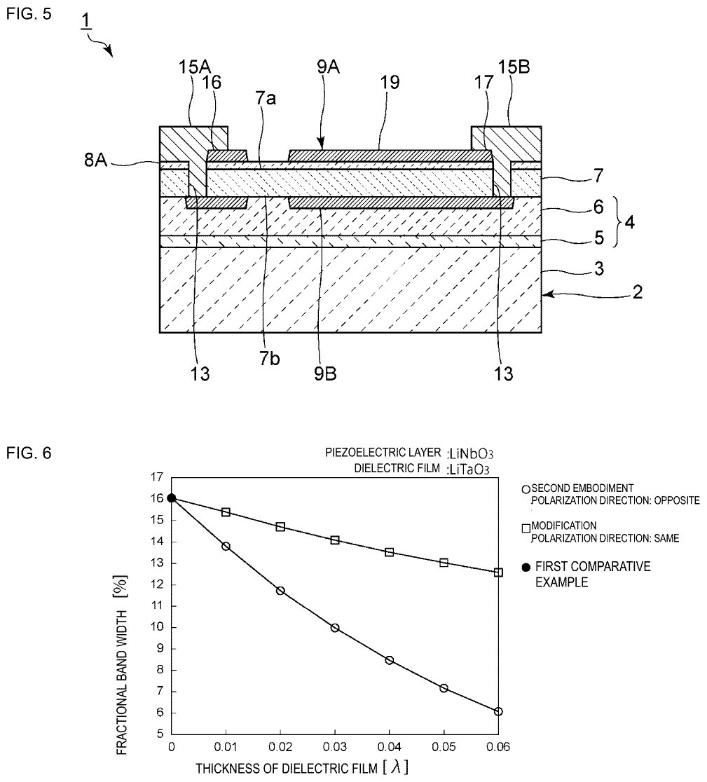

FIG. 5 is a cross-sectional view taken along a line II-II in FIG. 2.

A plurality of through holes 13 are provided to pass through the dielectric film 8A and the piezoelectric layer 7. One through hole 13 extends to one busbar of the second IDT electrode 9B. A first connection electrode 15A is provided continuously in the through hole 13 and on the dielectric film 8A. The first connection electrode 15A connects the one busbar of the second IDT electrode 9B and the first busbar 16 of the first IDT electrode 9A. Thus, the potential of the plurality of first electrode fingers 18 in the first IDT electrode 9A and the potential of the plurality of electrode fingers connected to the one busbar in the second IDT electrode 9B are in phase.

Another through hole 13 extends to the other busbar of the second IDT electrode 9B. A second connection electrode 15B is provided continuously in the through hole 13 and on the dielectric film 8A. The second connection electrode 15B connects the other busbar of the second IDT electrode 9B and the second busbar 17 of the first IDT electrode 9A. Thus, the potential of the plurality of second electrode fingers 19 in the first IDT electrode 9A and the potential of the plurality of electrode fingers connected to the other busbar in the second IDT electrode 9B are in phase.

Referring back to FIG. 2, in the first IDT electrode 9A, a region where adjacent electrode fingers overlap each other when viewed in the acoustic wave propagation direction is an overlap region A. Similarly, on the second principal surface 7b side of the piezoelectric layer 7, an overlap region is also defined by the configuration of the second IDT electrode 9B illustrated in FIG. 1. The overlap region A on the first principal surface 7a side and the overlap region on the second principal surface 7b side of the piezoelectric layer 7 overlap each other in plan view. To be more specific, the centers of the plurality of electrode fingers of the first IDT electrode 9A located in the overlap region A on the first principal surface 7a side of the piezoelectric layer 7 and the centers of the plurality of electrode fingers of the second IDT electrode 9B located in the overlap region on the second principal surface 7b side of the piezoelectric layer 7 overlap each other in plan view.

In this specification, “plan view” refers to a view from a side in a direction corresponding to the upper side in FIG. 1 and the like. In FIG. 1, for example, of the piezoelectric layer 7 side and the support substrate 3 side, the piezoelectric layer 7 side is the upper side.

It is sufficient that at least a portion of the plurality of electrode fingers of the first IDT electrode 9A and at least a portion of the plurality of electrode fingers of the second IDT electrode 9B overlap each other in plan view. More specifically, it is sufficient that the plurality of electrode fingers of the first IDT electrode 9A and the plurality of electrode fingers of the second IDT electrode 9B are in a state of overlapping each other in plan view within an error range that does not affect the electrical characteristics of the acoustic wave device 1. In the present specification, a case in which the above-described electrode fingers are in a state of deviating from the overlapping state in plan view due to a manufacturing variation is also included in the overlapping state in plan view.

In the first preferred embodiment, the potentials of the electrode fingers overlapping each other in plan view are in phase. However, the relationship between the potential of the electrode fingers of the first IDT electrode 9A and the potential of the electrode fingers of the second IDT electrode 9B is not limited to the relationship described above. For example, the potentials of at least one pair of electrode fingers among a plurality of pairs of electrode fingers overlapping each other in plan view may be in phase.

As illustrated in FIG. 1, the piezoelectric substrate 2 is a laminate substrate including the support substrate 3, the first layer 5 and the second layer 6 of the intermediate layer 4, and the piezoelectric layer 7. More specifically, in the first preferred embodiment, the first layer 5 defines and functions as a high acoustic velocity film. The high acoustic velocity film is a film with relatively high acoustic velocity. More specifically, the acoustic velocity of a bulk wave propagating through the high acoustic velocity film is higher than the acoustic velocity of an acoustic wave propagating through the piezoelectric layer 7. On the other hand, the second layer 6 defines and functions as a low acoustic velocity film. The low acoustic velocity film is a film with relatively low acoustic velocity. More specifically, the acoustic velocity of a bulk wave propagating through the low acoustic velocity film is lower than the acoustic velocity of a bulk wave propagating through the piezoelectric layer 7.

In the first preferred embodiment, the high acoustic velocity film, the low acoustic velocity film, and the piezoelectric layer 7 are laminated in this order in the piezoelectric substrate 2. As a result, the energy of the acoustic wave can be effectively confined to the piezoelectric layer 7 side.

When the first layer 5 of the intermediate layer 4 is a high acoustic velocity film, examples of the material of the high acoustic velocity film include piezoelectric materials such as aluminum nitride, lithium tantalate, lithium niobate, and quartz; ceramics such as alumina, sapphire, magnesia, silicon nitride, silicon carbide, zirconia, cordierite, mullite, steatite, forsterite, spinel, and sialon; dielectrics such as aluminum oxide, silicon oxynitride, diamond-like carbon (DLC), and diamond; semiconductors such as silicon; and materials including the above materials as main components. The spinel includes, for example, an aluminum compound including oxygen and one or more elements selected from Mg, Fe, Zn, Mn, and the like. Examples of the spinel include MgAl₂O₄, FeAl₂O₄, ZnAl₂O₄, and MnAl₂O₄. In the present specification, the term “main component” refers to a component whose proportion exceeds 50% by weight. The material of the main component may be provided in any of a single crystal state, a polycrystalline state and an amorphous state, or in a mixed state thereof.

When the second layer 6 is a low acoustic velocity film, examples of the material of the low acoustic velocity film include glass, silicon oxide, silicon oxynitride, lithium oxide, tantalum oxide, a dielectric such as a compound obtained by adding fluorine, carbon or boron to silicon oxide, and materials including the above materials as main components.

The intermediate layer 4 in the first preferred embodiment includes the second layer 6 as, for example, a silicon oxide layer. However, for example, when the intermediate layer 4 is a single dielectric layer, the intermediate layer 4 may be, for example, a silicon oxide layer. As discussed above, it is preferable for the intermediate layer 4 to include a layer using, for example, silicon oxide as a material. This makes it possible to reduce the absolute value of the temperature coefficient of frequency of the acoustic wave device 1, and improve the frequency-temperature characteristics of the acoustic wave device 1.

Examples of the material of the support substrate 3 include piezoelectric materials such as aluminum nitride, lithium tantalate, lithium niobate, and quartz; ceramics such as alumina, sapphire, magnesia, silicon nitride, silicon carbide, zirconia, cordierite, mullite, steatite, forsterite, spinel, and sialon; dielectrics such as aluminum oxide, silicon oxynitride, diamond-like carbon (DLC), and diamond; semiconductors such as silicon; and materials including the above materials as main components. Examples of the spinel include MgAl₂O₄, FeAl₂O₄, ZnAl₂O₄, and MnAl₂O₄.

In the acoustic wave device 1 of the first preferred embodiment, the piezoelectric layer 7 is, for example, an oxide layer including Li and Ta. The piezoelectric layer 7 may be, for example, an oxide layer including Li and Nb. This example will be described in a second preferred embodiment. The layer configuration of an acoustic wave device in the second preferred embodiment is the same as the layer configuration of the acoustic wave device 1 in the first preferred embodiment. Accordingly, the drawings and the reference signs used in the description of the first preferred embodiment will be used in the description of the second preferred embodiment.

In the second preferred embodiment, for example, LiNbO₃ of about 40° Y-cut X-propagation is used as the material of the piezoelectric layer 7 illustrated in FIG. 1. The Euler angles of LiNbO₃ used for the piezoelectric layer 7 are, for example, about (0°, 130°, 0°). LiTaO₃, for example, is used as the material of the dielectric film 8A. The Euler angles of LiTaO₃ used for the dielectric film 8A are, for example, about (0°, 130°, 0°). In the second preferred embodiment, the polarization direction of the dielectric film 8A is the same as the polarization direction of the piezoelectric layer 7.

The polarization direction of the dielectric film 8A and the polarization direction of the piezoelectric layer 7 may not be same. For example, in a modification of the second preferred embodiment indicated while referring to FIG. 1, the polarization direction of the dielectric film 8A is opposite to the polarization direction of the piezoelectric layer 7. Specifically, the Euler angles of LiTaO₃ used for the dielectric film 8A are, for example, about (0°, −50°, 0°).

In the second preferred embodiment and the modification thereof as well, each of the dielectric film 8A and the piezoelectric layer 7 includes one of Li, Ta, and O or Li, Nb, and O. Then, at least elements included in the materials of the dielectric film 8A and the piezoelectric layer 7 are different from each other. With this, as in the first preferred embodiment, the fractional band width of the acoustic wave device may be easily adjusted without increasing the size of the acoustic wave device.

In the acoustic wave device having the configuration of the second preferred embodiment and the acoustic wave device having the configuration of the modification of the second preferred embodiment, the relationship between the thickness of the dielectric film 8A and the fractional band width was derived by simulation. The design parameters of the acoustic wave device having the configuration of the second preferred embodiment are the same or substantially the same as the design parameters of the acoustic wave device 1, from which the relationships illustrated in FIGS. 3 and 4 were derived, except for the following parameters.
Piezoelectric layer 7: material: LiNbO₃, cut-angle: about 40° Y, Euler angles: about (0°, 130°, 0°), thickness: about 0.3λ
Dielectric film 8A: material: LiTaO₃, cut-angle: about 40° Y, Euler angles: about (0°, 130°, 0°), thickness: varied in increments of about 0.01λ in a range from about 0.01λ to about 0.06λ

The design parameters of the acoustic wave device having the configuration of the modification of the second preferred embodiment are different from the design parameters of the acoustic wave device having the configuration of the second preferred embodiment only in a point that the Euler angles of LiTaO₃ used for the dielectric film 8A are about (0°, −50°, 0°). In FIG. 6, the result of the first comparative example in which the thickness of the dielectric film is 0 is shown together with the results of the second preferred embodiment and each modification thereof. The design parameters of the first comparative example are the same or substantially the same as those of the acoustic wave device having the configuration of the second preferred embodiment except that the dielectric film is not provided.

FIG. 6 is a diagram illustrating a relationship between the thickness of the dielectric film and the fractional band width in the second preferred embodiment, the modification of the second preferred embodiment, and the first comparative example. The expression “POLARIZATION DIRECTION: OPPOSITE” in FIG. 6 indicates that the polarization directions of the dielectric film and the piezoelectric layer are opposite to each other. The expression “POLARIZATION DIRECTION: SAME” indicates that the dielectric film and the piezoelectric layer have the same polarization direction. The same applies to diagrams other than the diagram in FIG. 6 illustrating the relationship between the thickness of the dielectric film and the fractional band width.

As illustrated in FIG. 6, it is understood that the thicker the dielectric film 8A is, the smaller the value of the fractional band width is, in the second preferred embodiment and the modification thereof. Thus, in the second preferred embodiment and the modification thereof, the fractional band width can be easily adjusted by changing the thickness of the dielectric film 8A. In particular, in the second preferred embodiment, the thicker the dielectric film 8A is, the significantly smaller the value of the fractional band width is. Accordingly, it is preferable that the polarization direction of the dielectric film 8A and the polarization direction of the piezoelectric layer 7 are opposite to each other. Thus, the fractional band width may be even more easily adjusted by changing the thickness of the dielectric films 8A.

In the second preferred embodiment and the modification thereof, the material of the dielectric film 8A is, for example, oxide including Li and Ta. This makes it possible to suitably increase the dielectric constant of the dielectric film 8A. With this, even when the dielectric film 8A is provided on the piezoelectric layer 7, the electrostatic capacitance of the acoustic wave device is hardly reduced. The same applies to thickness adjustment of the dielectric film 8A. Accordingly, in the second preferred embodiment and the modification thereof, the fractional band width of the acoustic wave device may be easily adjusted without increasing the size of the acoustic wave device.

In the first and second preferred embodiments, elements included in the materials of the dielectric film 8A and the piezoelectric layer 7 are different from each other. However, it is sufficient that at least one of the polarization direction, an element included in the material, and the composition of the material is different between the dielectric film 8A and the piezoelectric layer 7. An example in which the dielectric film 8A and the piezoelectric layer 7 are different from each other only in the polarization direction will be described in a third preferred embodiment and a fourth preferred embodiment.

The layer configuration of an acoustic wave device in each of the third preferred embodiment and the fourth preferred embodiment of the present invention is the same as the layer configuration of the acoustic wave device 1 in the first preferred embodiment. Accordingly, the drawings and the reference signs used in the description of the first preferred embodiment will be used in the description of the third and fourth preferred embodiments.

The third preferred embodiment differs from the first preferred embodiment only in the material of the dielectric film 8A illustrated in FIG. 1. To be specific, for example, LiTaO₃ of about 50° Y-cut X-propagation is used as the material of the dielectric film 8A. The same applies to the material of the piezoelectric layer 7. However, in the dielectric film 8A and the piezoelectric layer 7, the polarization directions are opposite to each other.

The fourth preferred embodiment differs from the third preferred embodiment in that the dielectric film 8A illustrated in FIG. 1 has neither piezoelectric nor a polarization direction. Specifically, for example, LiTaO₃ is used as the material of the dielectric film 8A. The degree of dipole orientation in the dielectric film 8A is, for example 50%. The degree of dipole orientation is obtained by calculating the rate of a positive or negative direction in the polarization direction on the surface of the piezoelectric material, where any of the positive and negative directions having a larger proportion is selected for the calculation. When the degree of dipole orientation of the piezoelectric material is about 50%, the polarization in the positive direction and the polarization in the negative direction are present at the same or substantially the same rate, and therefore the piezoelectric material does not have piezoelectric. That is, in the case where the degree of dipole orientation is about 50%, it is indicated that there is no polarization direction and there is no piezoelectric. In the fourth preferred embodiment, the piezoelectric layer 7 has a polarization direction, while the dielectric film 8A does not have a polarization direction. That is, the degree of dipole orientation of the piezoelectric layer 7 and the degree of dipole orientation of the dielectric film 8A are different from each other. Therefore, the dielectric film 8A and the piezoelectric layer 7 have mutually different polarization directions.

In the third and fourth preferred embodiments as well, as in the first preferred embodiment, the fractional band width of the acoustic wave device may be easily adjusted without increasing the size of the acoustic wave device. This point will be described below by comparing the third preferred embodiment, the fourth preferred embodiment, and a second comparative example. The second comparative example is different from the third preferred embodiment and the fourth preferred embodiment in that the dielectric film and the piezoelectric layer have the same polarization direction, the same elements contained in the material, and the same composition of the material.

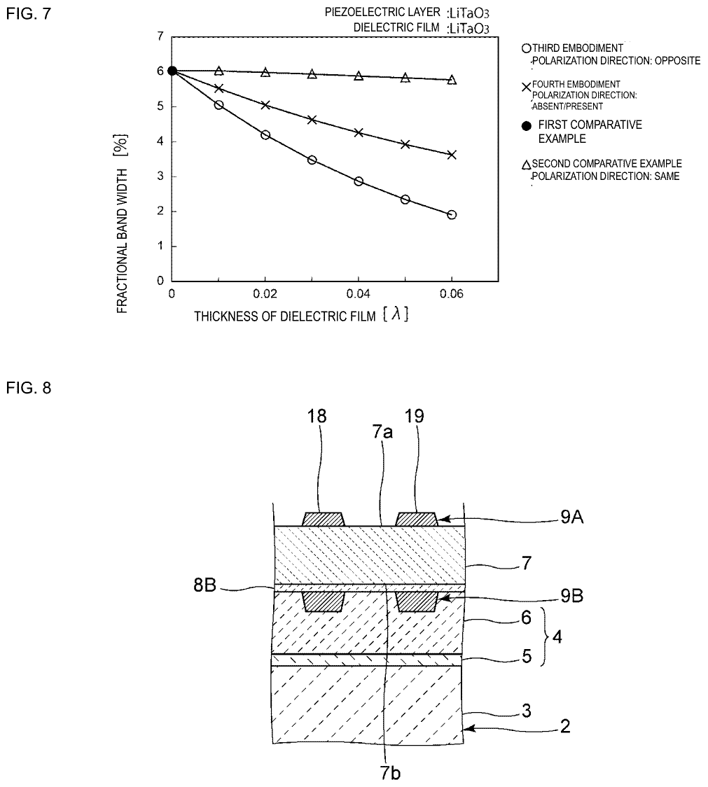

In the acoustic wave device having the configuration of the third preferred embodiment, the acoustic wave device having the configuration of the fourth preferred embodiment, and the acoustic wave device of the second comparative example, the relationship between the thickness of the dielectric film and the fractional band width was derived by simulation. The results thereof are shown in FIG. 7.

The design parameters of the acoustic wave device having the configuration of the third preferred embodiment are the same or substantially the same as the design parameters of the acoustic wave device 1, from which the relationships illustrated in FIGS. 3 and 4 were derived, except for the material of the dielectric film, the cut-angles, and the Euler angles. The same applies to the fourth preferred embodiment. The dielectric film in the acoustic wave device of the fourth preferred embodiment does not have a polarization direction. On the other hand, the design parameters of the acoustic wave device of the second comparative example are the same or substantially the same as the design parameters of the acoustic wave device having the configuration of the third preferred embodiment except for the Euler angles of the dielectric film. Specifically, the polarization direction of the dielectric film in the acoustic wave device of the second comparative example is opposite to the polarization direction of the dielectric film in the acoustic wave device having the configuration of the third preferred embodiment.

Furthermore, the fractional band width of the first comparative example different from the third preferred embodiment in that the dielectric film is not provided, was calculated by simulation. The result thereof is also shown in FIG. 7. The design parameters of the first comparative example are the same or substantially the same as those of the acoustic wave device having the configuration of the third preferred embodiment except that the dielectric film is not provided.

FIG. 7 is a diagram illustrating the relationship between the thickness of the dielectric film and the fractional band width in the third preferred embodiment, the fourth preferred embodiment, the first comparative example, and the second comparative example. In FIG. 7, the expression “POLARIZATION DIRECTION: ABSENT/PRESENT” indicates that the dielectric film does not have a polarization direction while the piezoelectric layer has a polarization direction. That is, the description before the slash mark indicates the presence or absence of the polarization direction of the dielectric film, while the description after the slash mark indicates the presence or absence of the polarization direction of the piezoelectric layer.

As illustrated in FIG. 7, in the second comparative example, even when the thickness of the dielectric film is changed, the value of the fractional band width hardly changes. The fractional band width in the second comparative example is almost the same as that in the first comparative example. In contrast, in the third and fourth preferred embodiments, the thicker the dielectric film is, the significantly smaller the value of the fractional band width is. Thus, in the third and fourth preferred embodiments, the fractional band width can be easily adjusted by changing the thickness of the dielectric film. In particular, in the third preferred embodiment, the change in the value of the fractional band width relative to the change in the thickness of the dielectric film is large. Therefore, in the third preferred embodiment, the fractional band width can be even more easily adjusted.

In addition, in the third and fourth preferred embodiments, the material of the dielectric film is, for example, oxide including Li and Ta. This makes it possible to suitably increase the dielectric constant of the dielectric film. Because of this, similarly to the first preferred embodiment, also in the third preferred embodiment, even when the dielectric film is provided on the piezoelectric layer, the electrostatic capacitance of the acoustic wave device is hardly reduced. Accordingly, the fractional band width of the acoustic wave device may be easily adjusted without increasing the size of the acoustic wave device.

In the present invention, the position where the dielectric film is provided is not limited to the first principal surface of the piezoelectric layer. Hereinafter, a fifth preferred embodiment and a sixth preferred embodiment which are different from the first preferred embodiment only in the arrangement of a dielectric film will be described. In the fifth and sixth preferred embodiments as well, as in the first preferred embodiment, the fractional band width of an acoustic wave device may be easily adjusted without increasing the size of the acoustic wave device.

FIG. 8 is a front cross-sectional view illustrating the vicinity of a pair of electrode fingers of each of IDT electrodes in the fifth preferred embodiment.

In the present preferred embodiment, a first IDT electrode 9A is provided directly on a first principal surface 7a of a piezoelectric layer 7. On the other hand, a dielectric film 8B is provided on a second principal surface 7b. Specifically, the dielectric film 8B is provided between the piezoelectric layer 7 and a second layer 6 of an intermediate layer 4. The dielectric film 8B is a second dielectric film.

A second IDT electrode 9B is indirectly provided on the second principal surface 7b of the piezoelectric layer 7 with the dielectric film 8B interposed therebetween. The second IDT electrode 9B is buried in the second layer 6 of the intermediate layer 4.

As in the first preferred embodiment, for example, LiTaO₃ of about 50° Y-cut X-propagation is used as the material of the piezoelectric layer 7. LiNbO₃ is used as the material of the dielectric film 8B, for example. In the dielectric film 8B and the piezoelectric layer 7, the polarization directions are opposite to each other.

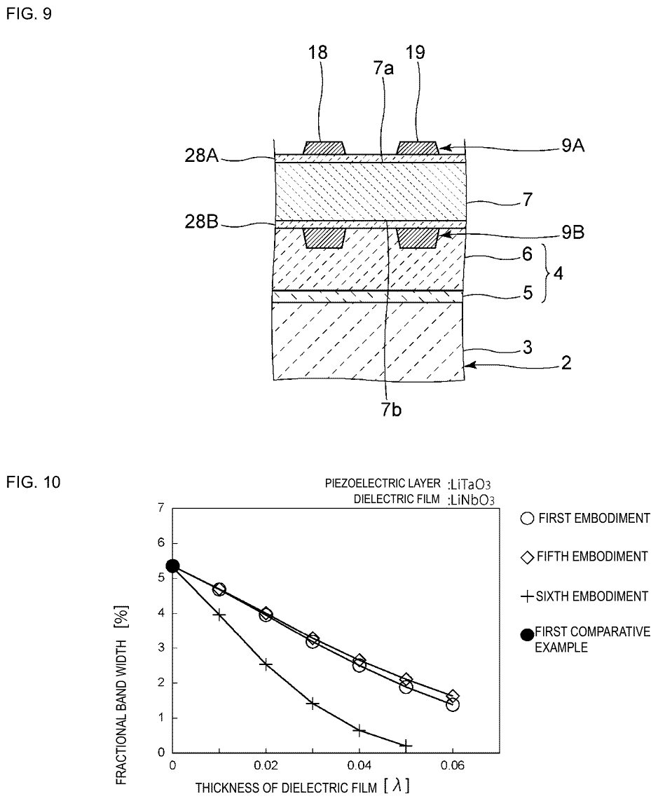

FIG. 9 is a front cross-sectional view illustrating the vicinity of a pair of electrode fingers of each of IDT electrodes in the sixth preferred embodiment.

In the present preferred embodiment, a first dielectric film 28A is provided between a first principal surface 7a of a piezoelectric layer 7 and a first IDT electrode 9A. A second dielectric film 28B is provided between a second principal surface 7b and a second IDT electrode 9B.

As in the first preferred embodiment, for example, LiTaO₃ of about 50° Y-cut X-propagation is used as the material of the piezoelectric layer 7. LiNbO₃ is used as the material of the first dielectric film 28A and the second dielectric film 28B, for example. The polarization directions of the first dielectric film 28A and the second dielectric film 28B are the same. On the other hand, the polarization directions of the first dielectric film 28A and the second dielectric film 28B are opposite to the polarization direction of the piezoelectric layer 7.

In the acoustic wave device having the configuration of the fifth preferred embodiment and the acoustic wave device having the configuration of the sixth preferred embodiment, the relationship between the thickness of the dielectric film and the fractional band width was derived by simulation. Further, in the acoustic wave device having the configuration of the fifth preferred embodiment and the acoustic wave device having the configuration of the sixth preferred embodiment, the relationship between the thickness of the dielectric film and the electrostatic capacitance was derived by simulation. In the acoustic wave device having the configuration of the sixth preferred embodiment, the thicknesses of the first dielectric film 28A and the second dielectric film 28B illustrated in FIG. 9 were the same or substantially the same.

The design parameters of the acoustic wave device having the configuration of the fifth preferred embodiment are the same or substantially the same as the design parameters of the acoustic wave device 1 having the configuration of the first preferred embodiment, from which the relationships in FIGS. 3 and 4 were derived, except for the dielectric film 8B. To be specific, the thickness of the dielectric film equivalent to the dielectric film 8A shown in FIG. 1 was set to be 0. On the other hand, the parameters of the dielectric film 8B provided on the second principal surface 7b of the piezoelectric layer 7 were set to be the same or substantially the same as the parameters of the dielectric film 8A.

The design parameters of the acoustic wave device having the configuration of the sixth preferred embodiment are the same or substantially the same as the design parameters of the acoustic wave device 1 except for the first dielectric film 28A and the second dielectric film 28B. Specifically, the cut-angles of the first dielectric film 28A and the second dielectric film 28B were made to be the same or substantially the same as the cut-angle of the dielectric film 8A, and the sum of the thicknesses of the first dielectric film 28A and the second dielectric film 28B was made to be the same as the thickness of the dielectric film 8A.

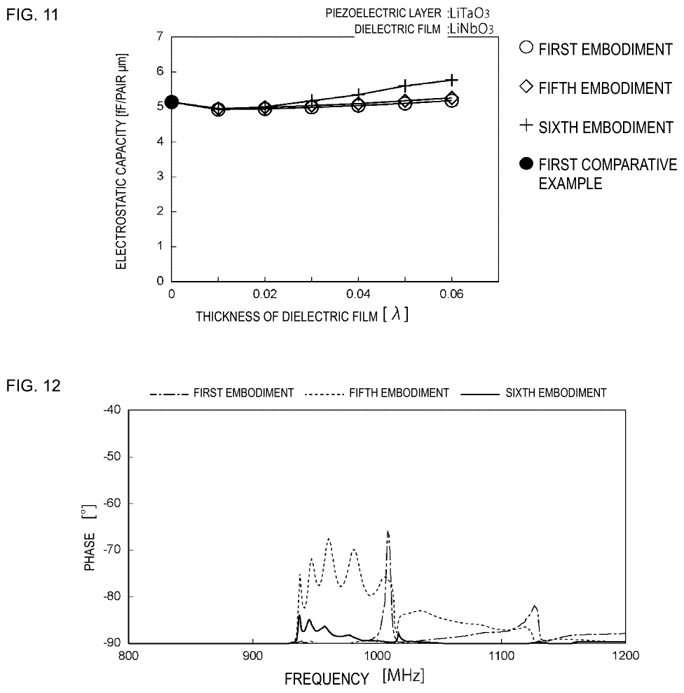

In FIGS. 10 and 11, the results of the first preferred embodiment and the first comparative example depicted in FIGS. 3 and 4 are illustrated together with the results of the fifth preferred embodiment and the sixth preferred embodiment.

FIG. 10 is a diagram illustrating the relationship between the thickness of the dielectric film and the fractional band width in the first preferred embodiment, the fifth preferred embodiment, the sixth preferred embodiment, and the first comparative example. FIG. 11 is a diagram illustrating the relationship between the thickness of the dielectric film and the electrostatic capacitance in the first preferred embodiment, the fifth preferred embodiment, the sixth preferred embodiment, and the first comparative example. In the acoustic wave device having the configuration of the sixth preferred embodiment, the thicknesses of the first dielectric film 28A and the second dielectric film 28B are each the thickness of the dielectric film indicated on the horizontal axis of each of FIGS. 10 and 11. For example, when the thickness of the dielectric film is about 0.02λ, the thicknesses of the first dielectric film 28A and the second dielectric film 28B are each about 0.02λ.

As illustrated in FIG. 10, it is understood that in any of the first preferred embodiment, fifth preferred embodiment, and sixth preferred embodiment, the thicker the dielectric film is, the significantly smaller the value of the fractional band width is. In particular, in the sixth preferred embodiment, it is understood that the change in the value of the fractional band width is large relative to the change in the thickness of the dielectric film. Accordingly, as illustrated in FIG. 9, it is preferable that both of the first dielectric film 28A and the second dielectric film 28B are provided. By doing so, the fractional band width can be adjusted even more easily.

On the other hand, as illustrated in FIG. 11, it is understood that in any of the first preferred embodiment, fifth preferred embodiment, and sixth preferred embodiment, even when the thickness of the dielectric film is changed, there is no significant change in the electrostatic capacitance of the acoustic wave device.

Furthermore, phase characteristics near a frequency at which a higher order mode is generated were measured in each of the acoustic wave device having the configuration of the first preferred embodiment, the acoustic wave device having the configuration of the fifth preferred embodiment, and the acoustic wave device having the configuration of the sixth preferred embodiment.

FIG. 12 is a diagram illustrating phase characteristics in the vicinity of a frequency at which a higher order mode is generated in the first preferred embodiment, the fifth preferred embodiment, and the sixth preferred embodiment.

As illustrated in FIG. 12, in each preferred embodiment, a higher order mode is generated in, for example, a range from about 900 MHz to about 1100 MHz. However, it is understood that the phase of the higher order mode is reduced or prevented to be less than about −82 degrees in the sixth preferred embodiment. Accordingly, as illustrated in FIG. 9, it is preferable that both of the first dielectric film 28A and the second dielectric film 28B are provided. As a result, the higher order mode may be effectively reduced or prevented.

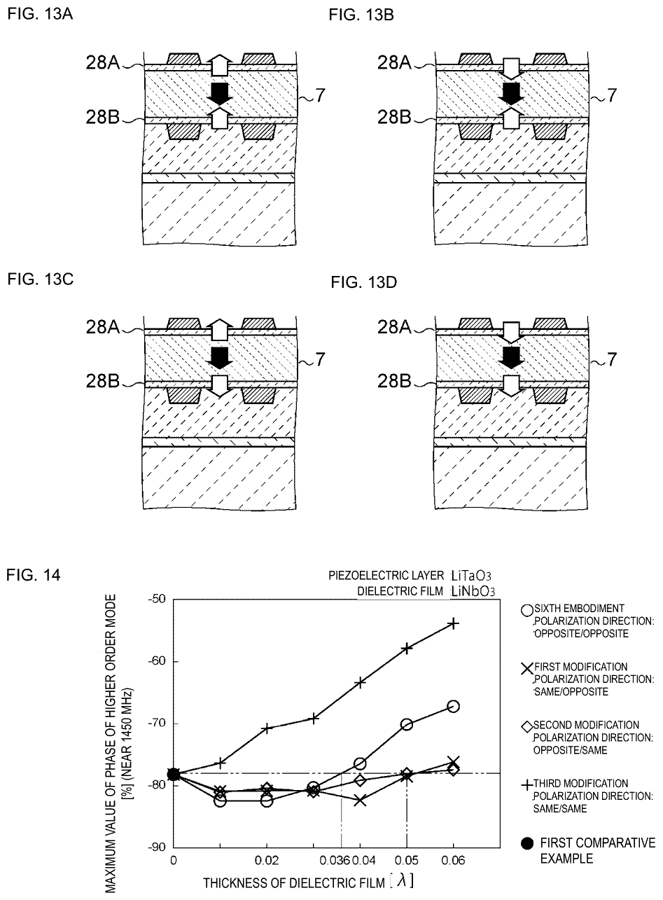

In the sixth preferred embodiment, as schematically illustrated in FIG. 13A, the polarization directions of the first dielectric film 28A and the second dielectric film 28B are opposite to the polarization direction of the piezoelectric layer 7. The relationship regarding the polarization directions described above may be the relationship regarding first to third modifications of the sixth preferred embodiment illustrated in FIGS. 13B to 13D. The first to third modifications are different from the sixth preferred embodiment only in the relationship between the polarization directions of the first dielectric film 28A and second dielectric film 28B and the polarization direction of the piezoelectric layer 7. That is, in each modification, as in the sixth preferred embodiment, elements included in the materials of the first dielectric film 28A and second dielectric film 28B are different from elements included in the material of the piezoelectric layer 7.

To be specific, in the first modification illustrated in FIG. 13B, the polarization direction of the first dielectric film 28A and the polarization direction of the piezoelectric layer 7 are the same, and the polarization direction of the second dielectric film 28B and the polarization direction of the piezoelectric layer 7 are opposite to each other. In the second modification illustrated in FIG. 13C, the polarization direction of the first dielectric film 28A and the polarization direction of the piezoelectric layer 7 are opposite to each other, and the polarization direction of the second dielectric film 28B and the polarization direction of the piezoelectric layer 7 are the same. In the third modification illustrated in FIG. 13D, the polarization directions of the first dielectric film 28A, the second dielectric film 28B, and the piezoelectric layer 7 are the same.

In the first to third modifications as well, as in the sixth preferred embodiment, the fractional band width of the acoustic wave device may be easily adjusted without increasing the size of the acoustic wave device.

Further, the influence of the polarization directions of the piezoelectric layer 7, the first dielectric film 28A, and the second dielectric film 28B on a higher order mode was examined. In the acoustic wave device having the configuration of the sixth preferred embodiment, the relationship between the thickness of the dielectric film and a maximum value of the phase of a higher order mode was derived by simulation. In the acoustic wave device having the configuration of each of the modifications of the sixth preferred embodiment, the relationship between the thickness of the dielectric film and a maximum value of the phase of a higher order mode was also derived by simulation.

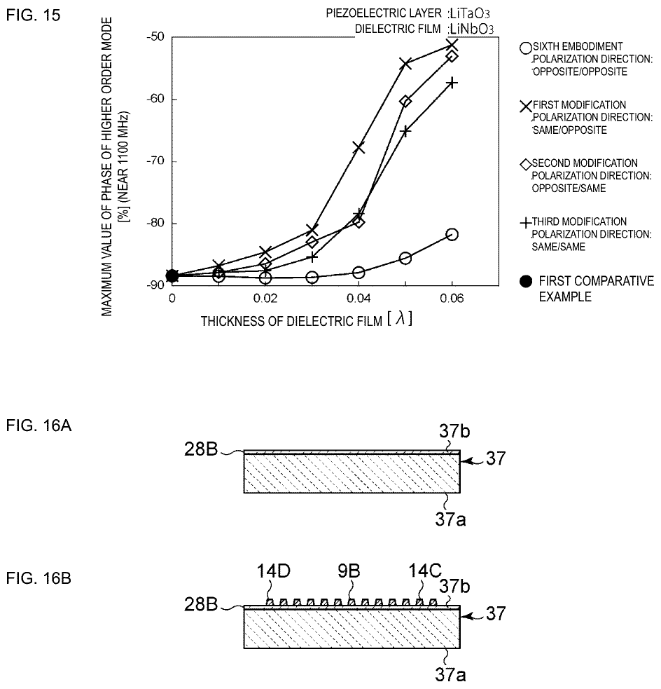

In this case, the thickness of the dielectric film is the thickness of each of the first dielectric film 28A and the second dielectric film 28B. In the sixth preferred embodiment and each modification thereof, the thicknesses of the first dielectric film 28A and the second dielectric film 28B are the same or substantially the same. The above relationship was derived for two kinds of higher order modes. More specifically, for example, the two kinds of higher order modes are a higher order mode generated near about 1450 MHz and a higher order mode generated near about 1100 MHz. In FIGS. 14 and 15, the result of the first comparative example in which the thickness of the dielectric film is 0 is shown together with the results of the sixth preferred embodiment and the modifications thereof.

FIG. 14 is a diagram illustrating the relationship between the thickness of the dielectric film and a maximum value of the phase of a higher order mode generated near about 1450 MHz in the sixth preferred embodiment, the first to third modifications of the sixth preferred embodiment, and the first comparative example. FIG. 15 is a diagram illustrating the relationship between the thickness of the dielectric film and a maximum value of the phase of a higher order mode generated near 1100 MHz in the sixth preferred embodiment, the first to third modifications of the sixth preferred embodiment, and the first comparative example. The expression “POLARIZATION DIRECTION: OPPOSITE/OPPOSITE” in FIGS. 14 and 15 indicates that the polarization directions of the first dielectric film and the piezoelectric layer are opposite to each other, and the polarization directions of the second dielectric film and the piezoelectric layer are also opposite to each other. That is, the description before the slash mark indicates the relationship between the polarization directions of the first dielectric film and the piezoelectric layer, while the description after the slash mark indicates the relationship between the polarization directions of the second dielectric film and the piezoelectric layer.

As illustrated in FIG. 14, in the cases other than the third modification case, it is understood that the higher order mode generated near 1450 MHz can be further reduced or prevented than in the first comparative example by setting the thickness of the dielectric film within a predetermined range.

In the sixth preferred embodiment, the polarization directions of the first dielectric film 28A and the second dielectric film 28B are opposite to the polarization direction of the piezoelectric layer 7. In this case, the sum of the thicknesses of the first dielectric film 28A and the second dielectric film 28B is preferably, for example, about 0.036λ or less, and more preferably about 0.03λ or less. This makes it possible to reduce or prevent the higher order mode generated near 1450 MHZ.

In the first modification and the second modification, one of the polarization directions of the first dielectric film 28A and the second dielectric film 28B is opposite to the polarization direction of the piezoelectric layer 7. In this case, the sum of the thicknesses of the first dielectric film 28A and the second dielectric film 28B is preferably, for example, about 0.05λ or less, and more preferably about 0.04λ or less. This makes it possible to reduce or prevent the higher order mode generated near 1450 MHZ.

As illustrated in FIG. 15, in the sixth preferred embodiment, it is understood that the higher order mode generated near 1100 MHz can be more reduced or prevented than in the first comparative example by setting the thickness of the dielectric film within a predetermined range. That is, for example, about 0.04λ or less is preferred, and about 0.03λ or less is more preferred. This makes it possible to reduce or prevent the higher order mode generated near 1100 MHz.

It is sufficient that at least one of the polarization direction, an element contained in the material, and the composition of the material is different between the first and second dielectric films 28A and 28B, and the piezoelectric layer 7 illustrated in FIG. 9. In this case, it is preferable that the degree of dipole orientation of at least one of the first dielectric film 28A and the second dielectric film 28B is different from the degree of dipole orientation of the piezoelectric layer 7. By doing so, the fractional band width of the acoustic wave device can be adjusted even more easily. For example, at least one of the first dielectric film 28A and the second dielectric film 28B may not be piezoelectric.

An example of a manufacturing method for the acoustic wave device according to the sixth preferred embodiment will be described below.

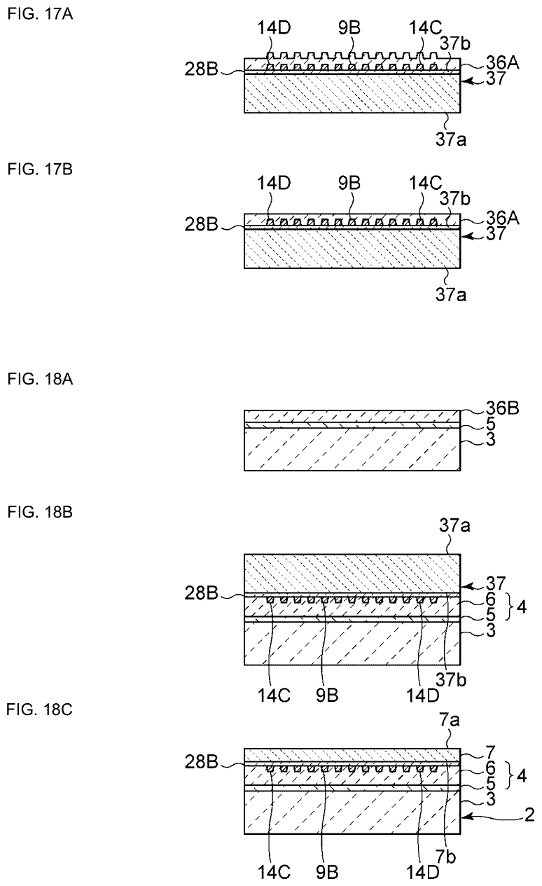

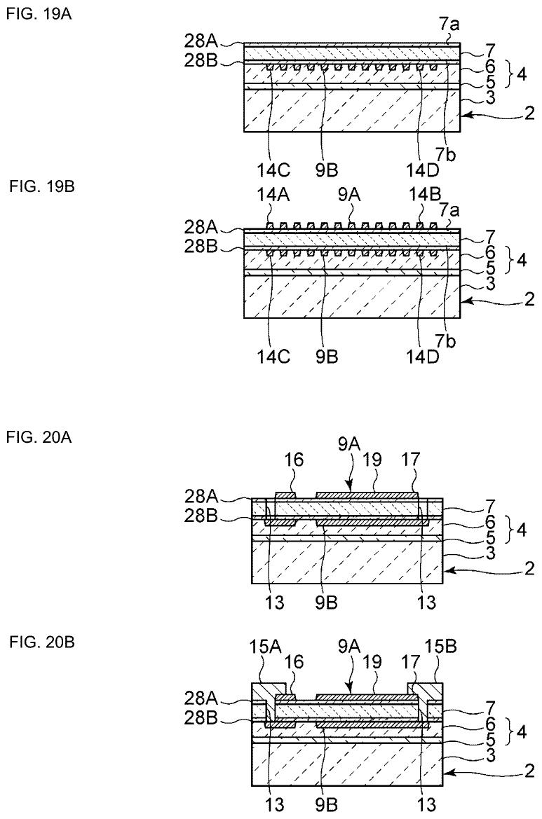

FIGS. 16A and 16B are front cross-sectional views describing processes performed until the second IDT electrode is provided in the example of the manufacturing method for the acoustic wave device according to the sixth preferred embodiment. FIGS. 17A and 17B are front cross-sectional views describing processes performed until a dielectric layer is provided in the example of the manufacturing method for the acoustic wave device according to the sixth preferred embodiment. FIGS. 18A to 18C are front cross-sectional views describing processes performed until the thickness of a piezoelectric substrate is adjusted in the example of the manufacturing method for the acoustic wave device according to the sixth preferred embodiment. FIGS. 19A and 19B are front cross-sectional views describing processes performed until the first IDT electrode is provided in the example of the manufacturing method for the acoustic wave device according to the sixth preferred embodiment. FIGS. 20A and 20B are cross-sectional views taken along a direction in which electrode fingers extend for describing processes carried out until a first connection electrode and a second connection electrode are provided in the example of the manufacturing method for the acoustic wave device according to the sixth preferred embodiment.

As illustrated in FIG. 16A, a piezoelectric substrate 37 is prepared. The piezoelectric substrate 37 includes a third principal surface 37a and a fourth principal surface 37b. The third principal surface 37a and the fourth principal surface 37b oppose each other. Subsequently, the second dielectric film 28B is provided on the fourth principal surface 37b of the piezoelectric substrate 37. The second dielectric film 28B may be deposited by, for example, a sputtering method or a vacuum vapor deposition method.

For example, the second dielectric film 28B may be formed by, for example, pasting a substrate made of the same material as that of the second dielectric film 28B onto the fourth principal surface 37b of the piezoelectric substrate 37 and then thinning the pasted substrate. When the substrate is thinned, for example, grinding, a chemical mechanical polishing (CMP) method, or etching may be used.

Subsequently, as illustrated in FIG. 16B, the second IDT electrode 9B is provided on the second dielectric film 28B. At the same time, a reflector 14C and a reflector 14D are provided on the second dielectric film 28B. The second IDT electrode 9B and the reflectors may be formed by, for example, a lift-off method using a sputtering method or a vacuum vapor deposition method.

Next, as illustrated in FIG. 17A, a dielectric layer 36A is provided on the second dielectric film 28B to cover the second IDT electrode 9B. The dielectric layer 36A may be formed by, for example, a sputtering method or a vacuum vapor deposition method. Subsequently, as illustrated in FIG. 17B, the dielectric layer 36A is flattened. For flattening the dielectric layer 36A, for example, grinding or a CMP method may be used. As the material of the dielectric layer 36A, the same material as that of a second layer 6 of an intermediate layer 4 illustrated in FIG. 9 can be used. In this example of the manufacturing method, the material of the dielectric layer 36A is silicon oxide.

Meanwhile, as illustrated in FIG. 18A, a first layer 5 is provided on a support substrate 3. Subsequently, a dielectric layer 36B is provided on the first layer 5. Each of the first layer 5 and the dielectric layer 36B may be formed by, for example, a sputtering method or a vacuum vapor deposition method. As the material of the dielectric layer 36B, the same material as that of the second layer 6 of the intermediate layer 4 illustrated in FIG. 9 may be used. In this example of the manufacturing method, the material of the dielectric layer 36B is silicon oxide.

Next, the dielectric layer 36A illustrated in FIG. 17B and the dielectric layer 36B illustrated in FIG. 18A are bonded to each other. With this, as illustrated in FIG. 18B, the second layer 6 is formed, and the support substrate 3 and the piezoelectric substrate 37 are bonded to each other. Thus, a multilayer body formed of the piezoelectric substrate 37, the intermediate layer 4, and the support substrate 3 is obtained.

Next, the thickness of the piezoelectric substrate 37 is adjusted. To be more specific, the third principal surface 37a side of the piezoelectric substrate 37 is ground or polished to reduce the thickness of the piezoelectric substrate 37. For example, grinding, a CMP method, an ion slicing method, or etching can be used to adjust the thickness of the piezoelectric substrate 37. With this, as illustrated in FIG. 18C, the piezoelectric layer 7 is obtained.

Next, as illustrated in FIG. 19A, the first dielectric film 28A is provided on the first principal surface 7a of the piezoelectric layer 7. The first dielectric film 28A may be deposited by, for example, a sputtering method or a vacuum vapor deposition method. For example, the first dielectric film 28A may be formed by pasting a substrate made of the same material as that of the first dielectric film 28A onto the first principal surface 7a of the piezoelectric layer 7 and then thinning the pasted substrate. When the substrate is thinned, for example, grinding, a CMP method, or etching can be used.

Subsequently, as illustrated in FIG. 19B, the first IDT electrode 9A is provided on the first dielectric film 28A. At the same time, a reflector 14A and a reflector 14B are provided on the first dielectric film 28A. The first IDT electrode 9A and the reflectors may be formed by, for example, a lift-off method using a sputtering method or a vacuum vapor deposition method.

Next, as illustrated in FIG. 20A, a plurality of through holes 13 are provided in the first dielectric film 28A, the piezoelectric layer 7, and the second dielectric film 28B. To be more specific, the through holes 13 extending to one of the busbars of the second IDT electrode 9B and the through holes 13 extending to the other one of the busbars thereof are provided. The plurality of through holes 13 may be formed by, for example, a reactive ion etching (RIE) method.

Subsequently, as illustrated in FIG. 20B, a first connection electrode 15A is continuously provided in the through hole 13 extending to the one of the busbars of the second IDT electrode 9B and on the first dielectric film 28A. The first connection electrode 15A is provided to extend to a first busbar 16 of the first IDT electrode 9A. With this, the one of the busbars of the second IDT electrode 9B and the first busbar 16 of the first IDT electrode 9A are connected by the first connection electrode 15A.

Further, a second connection electrode 15B is continuously provided in the through hole 13 extending to the other one of the busbars of the second IDT electrode 9B and on the first dielectric film 28A. The second connection electrode 15B is provided to extend to a second busbar 17 of the first IDT electrode 9A. With this, the other one of the busbars of the second IDT electrode 9B and the second busbar 17 of the first IDT electrode 9A are connected by the second connection electrode 15B. The first connection electrode 15A and the second connection electrode 15B may be formed by, for example, a lift-off method using a sputtering method or a vacuum vapor deposition method. In the manner described above, the acoustic wave device is achieved.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a support substrate;
a piezoelectric layer on the support substrate and including a first principal surface and a second principal surface opposing each other;
a first IDT electrode on the first principal surface of the piezoelectric layer, and a second IDT electrode on the second principal surface of the piezoelectric layer; and
a dielectric film at least provided at one of a position between the first principal surface of the piezoelectric layer and the first IDT electrode and a position between the second principal surface of the piezoelectric layer and the second IDT electrode; wherein
each of the dielectric film and the piezoelectric layer includes one of Li, Ta, and O or Li, Nb, and O; and
at least one of a polarization direction, an element included in a material, and a composition of the material is different between the dielectric film and the piezoelectric layer.

2. The acoustic wave device according to claim 1, wherein
the dielectric film includes a first dielectric film and a second dielectric film; and
the first dielectric film is between the first principal surface of the piezoelectric layer and the first IDT electrode, and the second dielectric film is between the second principal surface and the second IDT electrode.

3. The acoustic wave device according to claim 2, wherein a polarization direction of at least one of the first dielectric film and the second dielectric film is opposite to a polarization direction of the piezoelectric layer.

4. The acoustic wave device according to claim 3, wherein both of the polarization directions of the first dielectric film and the second dielectric film are opposite to the polarization direction of the piezoelectric layer.

5. The acoustic wave device according to claim 2, wherein a degree of dipole orientation of at least one of the first dielectric film and the second dielectric film is different from a degree of dipole orientation of the piezoelectric layer.

6. The acoustic wave device according to claim 5, wherein at least one of the first dielectric film and the second dielectric film does not have piezoelectricity.

7. The acoustic wave device according to claim 1, further comprising an intermediate layer between the support substrate and the piezoelectric layer.

8. The acoustic wave device according to claim 7, wherein the intermediate layer includes a layer including silicon oxide.

9. The acoustic wave device according to claim 1, wherein the piezoelectric layer includes a piezoelectric single crystal.

10. The acoustic wave device according to claim 7, wherein the intermediate layer includes a first layer on the support substrate, and a second layer on the first layer.

11. The acoustic wave device according to claim 1, wherein the support substrate includes silicon.

12. The acoustic wave device according to claim 11, wherein a plane orientation of the silicon is (100).

13. The acoustic wave device according to claim 10, wherein the first layer includes silicon nitride, and the second layer includes silicon oxide.

14. The acoustic wave device according to claim 1, wherein the dielectric film includes lithium niobate.

15. The acoustic wave device according to claim 1, further comprising a protective film on the dielectric film and covering the first IDT electrode.

16. The acoustic wave device according to claim 15, wherein the protective film includes at least one of silicon oxide, silicon nitride, or silicon oxynitride.

17. The acoustic wave device according to claim 1, wherein the first IDT electrode includes:
a first busbar;
a second busbar;
a plurality of first electrode fingers; and
a plurality of second electrode fingers; wherein
one end of each of the plurality of first electrode fingers is connected to the first busbar;
one end of each of the plurality of second electrode fingers is connected to the second busbar; and
the plurality of first electrode fingers and the plurality of second electrode fingers are interdigitated with each other.

18. The acoustic wave device according to claim 1, wherein the second IDT electrode includes:
a first busbar;
a second busbar;
a plurality of first electrode fingers; and
a plurality of second electrode fingers; wherein
one end of each of the plurality of first electrode fingers is connected to the first busbar;
one end of each of the plurality of second electrode fingers is connected to the second busbar; and
the plurality of first electrode fingers and the plurality of second electrode fingers are interdigitated with each other.

19. The acoustic wave device according to claim 1, further comprising a pair of reflectors on both sides of the first IDT electrode in an acoustic wave propagation direction.

20. The acoustic wave device according to claim 1, further comprising a pair of reflectors on both sides of the second IDT electrode in an acoustic wave propagation direction.
